(19) United States
(12) Patent Application Publication
(10) Pub. No.: US 2026/0262180 A1
(43) Pub. Date: Sep. 3, 2026

(54) ELECTRONIC DEVICE

(71) Applicant: InnoLux Corporation, Miao-Li County (TW)

(72) Inventors: Chia-Che CHANG, Miao-Li County (TW); Guan-Jie DU, Miao-Li County (TW); Po-Ming HUANG, Miao-Li County (TW); Jen-Hsiang YEN, Miao-Li County (TW); Ping-Shan KO, Miao-Li County (TW); Shih-Hua CHI, Miao-Li County (TW)

(21) Appl. No.: 19/532,236

(22) Filed: Feb. 6, 2026

(30) Foreign Application Priority Data
Mar. 3, 2025 (CN) 202510243096.2

(51) Int. Cl. H05K 5/02

(52) U.S. Cl. CPC H05K 5/0226

(57) ABSTRACT

An electronic device having a first state and a second state includes a base and a display device. The display device includes multiple display units and multiple connection mechanisms for connecting adjacent two display units, wherein a first portion and a second portion of the display device overlap with the base in the first state, the first portion overlaps with the base in the second state, and the second portion does not overlaps with the base in the second state. Each of the plurality of connection mechanisms includes a pivot member, a screw rod connected with the pivot member, an inner bracket disposed adjacent to the screw rod, and a first slider disposed between the screw rod and the inner bracket, wherein the screw rod rotates to cause the first slider to move in the inner bracket, and the first slider drives the pivot member to rotate.

### CROSS-REFERENCE TO RELATED APPLICATIONS

This application claims the benefits of the Chinese Patent Application Serial Number 202510243096.2, filed on Mar. 3, 2025, the subject matter of which is incorporated herein by reference.

### BACKGROUND

### Field of the Disclosure

The present disclosure relates to an electronic device and, more particularly, to a foldable electronic device.

### Description of Related Art

Currently, the large-sized electronic device, such as the large-sized display composed of a plurality display units, is not easy to carry due to its large size.

Therefore, it is desired to provide an improved electronic device to alleviate and/or obviate the aforementioned problems.

### SUMMARY

The present disclosure includes an electronic device having a first state and a second state, which comprises: a base; and a display device including: a plurality of display units disposed on the base; and a plurality of connection mechanisms, wherein one of the plurality of connection mechanisms connects two adjacent display units of the plurality of display units, wherein the display device includes a first portion and a second portion, the first portion and the second portion overlap with the base in the first state, the first portion overlaps with the base in the second state, and the second portion does not overlap with the base in the second state, wherein the one of the plurality of connection mechanisms includes: a pivot member; a screw rod connected to the pivot member; an inner bracket disposed adjacent to the screw rod; and a first slider disposed between the screw rod and the inner bracket, wherein rotation of the screw rod causes the first slider to move within the inner bracket, and the first slider drives the pivot member to rotate.

Other novel features of the disclosure will become more apparent from the following detailed description when taken in conjunction with the accompanying drawings.

### BRIEF DESCRIPTION OF DRAWINGS

FIG. 1A is a schematic diagram of the electronic device in the first state according to an embodiment of the present disclosure;

FIG. 1B is a schematic diagram illustrating the process of the electronic device transitioning from the first state to the second state according to an embodiment of the present disclosure;

FIG. 1C is a schematic diagram of the electronic device in the second state according to an embodiment of the present disclosure;

FIG. 2 is a schematic diagram of the base according to an embodiment of the present disclosure;

FIG. 3A is a top view of the electronic device in the first state according to an embodiment of the present disclosure;

FIG. 3B is a top view of the electronic device in the second state according to an embodiment of the present disclosure;

FIG. 4 is a schematic diagram of the connection mechanism according to an embodiment of the present disclosure;

FIG. 5 is a schematic diagram of the connection mechanism according to another embodiment of the present disclosure

FIG. 6A illustrates a first stage of the transition of the electronic device from the first state to the second state;

FIG. 6B illustrates a second stage of the transition of the electronic device from the first state to the second state;

FIG. 6C illustrates a third stage of the transition of the electronic device from the first state to the second state;

FIG. 6D illustrates a fourth stage of the transition of the electronic device from the first state to the second state;

FIG. 7A illustrates a first stage of the transition of the electronic device from the second state to the first state;

FIG. 7B illustrates a second stage of the transition of the electronic device from the second state to the first state;

FIG. 7C illustrates a third stage of the transition of the electronic device from the second state to the first state; and

FIG. 7D illustrates a fourth stage of the transition of the electronic device from the second state to the first state.

### DETAILED DESCRIPTION OF EMBODIMENT

Reference will now be made in detail to exemplary embodiments of the present disclosure, examples of which are illustrated in the accompanying drawings. Wherever possible, the same reference numerals are used in the drawings and description to refer to the same or like parts.

In the entire specification and appended claims of the present disclosure, certain words are used to refer to specific components. Those skilled in the art should understand that electronic device manufacturers may refer to the same components by different names. The present disclosure does not intend to distinguish those components with the same function but different names. In the following description and claims, words such as “comprising”, “including”, and “having” are open type words, so they should be interpreted as meaning “including but not limited to”.

The terms “about”, “equal to”, “equal” or “same”, “substantially” or “approximately” are generally interpreted as being within 20% of a given value or range, or interpreted as being within 10%, 5%, 3%, 2%, 1%, or 0.5% of a given value or range.

In addition, it should be understood that, unless otherwise specified, the ordinal numbers used in the specification and claims, such as “first” and “second”, are intended to distinguish elements rather than disclose explicitly or implicitly that names of the elements bear the wording of the ordinal numbers. The ordinal numbers do not imply what order an element and another element are in terms of space, time or steps of a manufacturing method. Thus, what is referred to as a “first element” in the specification may be referred to as a “second element” in the claims.

In the present disclosure, the expressions “the given range is from the first numerical value to the second numerical value” and “the given range falls within the range from the first numerical value to the second numerical value” indicate that the given range includes the first numerical value, the second numerical value, and other numerical values therebetween.

In addition, the electronic device of the present disclosure may include display device, automation equipment, clamping device, computing device, mechanical equipment, drug dispensing equipment, exposure device, printing device, three-dimensional printing device, automotive device, imaging device, assembly device, backlight device, antenna device, tiled device, touch electronic device, curved electronic device, or free shape electronic device, but not limited thereto. The display device may, for example, include liquid crystal, light emitting diodes, fluorescence, phosphor, other suitable display media, or a combination thereof, but not limited thereto. The display device may be a non-self-luminous display device or a self-luminous display device. The antenna device may be a liquid crystal antenna device or a non-liquid crystal antenna device, and the sensing device may be a sensing device that senses capacitance, light, heat, or ultrasound, but not limited thereto. The tiled device may, for example, include a display tiled device or an antenna tiled device, but not limited thereto. It should be noted that the electronic device may be any of the aforementioned arrangements and combinations, but not limited thereto. In addition, the electronic device may be a bendable or flexible electronic device. It should be noted that the electronic device may be any of the aforementioned arrangements and combinations, but not limited thereto. In addition, the appearance of the electronic device may be rectangular, circular, polygonal, a shape with curved edges, or other suitable shapes. The electronic device may have peripheral systems such as a drive system, a control system, a light source system, a shelf system, etc. to support a display device, an antenna device, or a tiled device. For ease of explanation, in the present disclosure, the electronic device is exemplified by including a display device.

It is noted that, in the following embodiments, without departing from the spirit of the present disclosure, the features in different embodiments may be replaced, reorganized, and mixed to complete other embodiments. As long as the features of the various embodiments do not violate or conflict the spirit of the invention, they may be mixed and matched arbitrarily.

Unless otherwise defined, all terms (including technical and scientific terms) used herein have the same meaning as commonly understood by those skilled in the art to which the present disclosure belongs. It can be understood that these terms, such as those defined in commonly used dictionaries, should be interpreted as having meanings consistent with the background or context of the related technology and the present disclosure, and should not be interpreted in an idealized or overly formal manner, unless otherwise specified in the embodiments of the present disclosure.

In addition, the term “adjacent” in the specification and claims is used to describe mutual proximity, and does not necessarily mean mutual contact.

In addition, the description of “when . . . ” or “while . . . ” in the present disclosure means “now, before, or after”, etc., and is not limited to occurrence at the same time. In the present disclosure, the similar description of “disposed on” or the like refers to the corresponding positional relationship between the two elements, and does not limit whether there is contact between the two elements, unless specifically limited. Furthermore, when the present disclosure recites multiple effects, if the word “or” is used between the effects, it means that the effects can exist independently, but it does not exclude that multiple effects can exist at the same time.

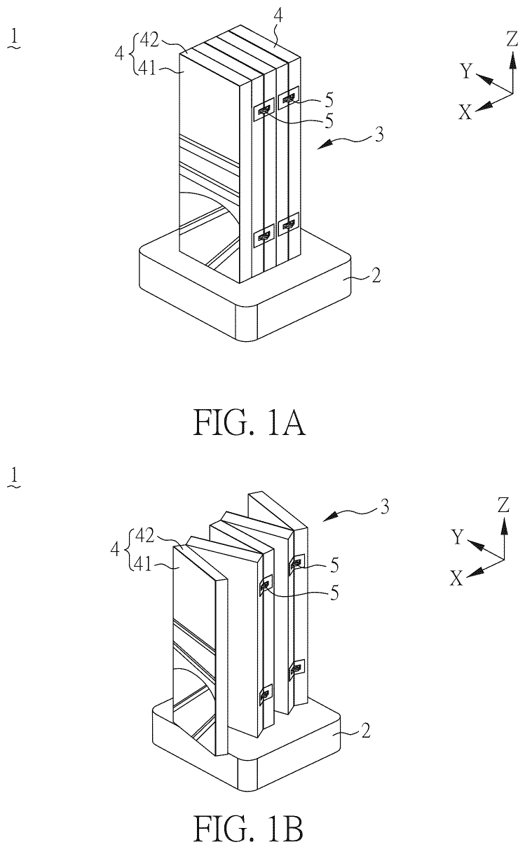

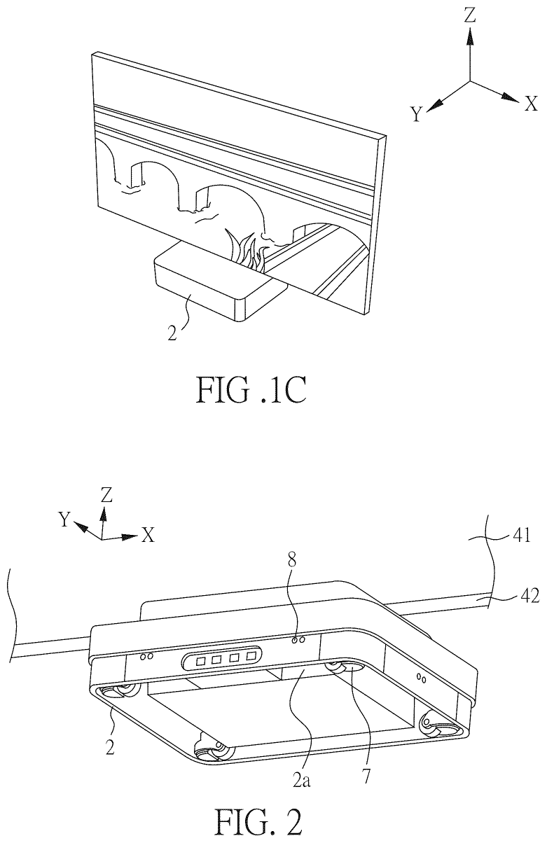

The electronic device 1 of the present disclosure is provided with a first state and a second state. Please refer to FIG. 1A to FIG. 1C, wherein FIG. 1A is a schematic diagram of the electronic device 1 in the first state according to an embodiment of the present disclosure, FIG. 1B is a schematic diagram illustrating the process of the electronic device 1 transitioning from the first state to the second state according to an embodiment of the present disclosure, and FIG. 1C is a schematic diagram of the electronic device 1 in the second state according to an embodiment of the present disclosure.

The electronic device 1 at least includes a base 2 and a display device 3. The display device 3 includes a plurality of display units 4 and a plurality of connection mechanisms 5. The display units 4 may be mounted on the base 2. One of the plurality of connection mechanisms 5 may connect two adjacent display units 4 of the plurality of display units 4. In one embodiment, each display unit 4 may include a display panel 41 and a back cover 42. The display panel 41 may be mounted on the back cover 42.

As shown in FIG. 1A, in the first state, the display device 3 may be in a retracted state (for example, a folded state), wherein, for example, the plurality of display units 4 at least partially overlap in a direction (for example, the X direction). For example, the display panels 41 of the plurality of display units 4 may overlap in the X direction, that is, the display direction of each display panel 41 may be oriented in the X direction or the negative X direction, but it is not limited thereto. In other words, in the first state, the plurality of display units 4 may be stacked together. The X direction is perpendicular to the Y direction, and the X direction and Y direction are each perpendicular to the Z direction.

As shown in FIG. 1B, during the transition from the first state to the second state, the display device 3 gradually transitions from the retracted state to the unfolded state, wherein an angle may be formed between every two adjacent display units 4.

As shown in FIG. 1C, in the second state, the display device 3 may be in a fully unfolded state. In this state, the display panels 41 of the plurality of display units 4 may be arranged in a first direction and joined together, and the display direction of each display panel 41 may be oriented in a second direction. In some embodiments, a portion of the display panels 41 may be oriented in the second direction, while another portion of the display panels 41 may be oriented in a direction opposite to the second direction. The so-called opposite direction means a phase difference of approximately 180 degrees from the original direction. In other embodiments, the display panels 41 may perform display in both the second direction and the direction opposite to the second direction at the same time. The first direction and the second direction may be perpendicular to each other. For example, when the first direction is the X direction and when the plurality of display units 4 are arranged and joined together along the X direction, the display panel 41 of each display unit 4 may be oriented in the Y direction, which is perpendicular to the X direction. In this way, the joined display panels 41 may form a large-sized display panel, for example, while it is not limited thereto.

In addition, referring to FIG. 1A to FIG. 1C, in one embodiment, when transitioning from the first state to the second state, that is, from the retracted state to the unfolded state, the display unit 4 of the display device 3 may be unfolded outward from two opposite sides. However, in other embodiments, the display unit 4 of the display device 3 may also be unfolded outward from one side, while it is not limited thereto. One advantage of the design of being unfolded outward from two opposite sides is that the electronic device 1 may be placed in the middle of a TV wall, rather than being limited to being placed on one side of the TV wall. Alternatively, one advantage of the design of being unfolded outward from two opposite sides is that, in the unfolded state, the display device 3 may be supported by the base 2 below its center, and the weight of the unfolded display units 4 may be evenly distributed on both sides, thereby achieving better balance (compared to the design of being unfolded outward from one side).

In addition, it should be noted that the directions in the above examples are only examples. In fact, during the process of transition from the first state to the second state, each display unit 4 itself may rotate relative to the base 2. Therefore, in fact, in the second state, the final display direction of the display unit 4 as a whole (the aforementioned second direction) is not necessarily toward the Y direction.

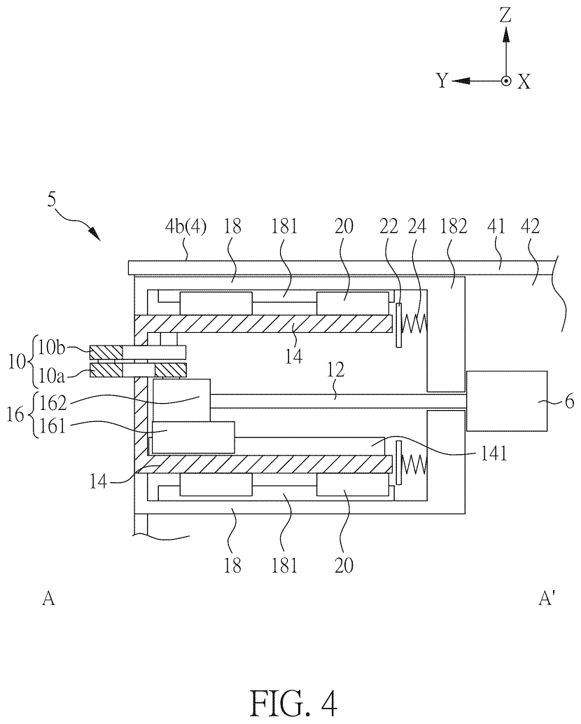

In one embodiment, the electronic device 1 may achieve transition between the first state and the second state via a connection mechanism 5. In one embodiment, the connection mechanism 5 may be controlled by a drive element 6 (shown in FIG. 4), while it is not limited thereto. In one embodiment, the drive element 6 may be, for example, a motor or other similar mechanism, but it is not limited thereto.

Accordingly, one of the features of the present disclosure is that the electronic device 1 of the present disclosure may be switched between a first state and a second state. Therefore, when the electronic device 1 needs to be transported, the display device 3 may be converted to a retracted state (first state) so as to reduce the volume and facilitate transportation. When the electronic device 1 needs to perform display, the display device 3 may be converted to an unfolded state (second state) and, at this moment, the plurality of display units 4 may be connected together to provide a large-size display panel.

FIG. 2 is a schematic diagram of the base 2 according to an embodiment of the present disclosure, and please refer to FIG. 1A to FIG. 1C at the same time. As shown in FIG. 2, in one embodiment, the base 2 may include a base body 2a and a movable element 7. In one embodiment, the movable element 7 may be disposed on the base body 2a or other parts of the base body 2a. In one embodiment, the movable element 7 may include wheels, and in the Z direction, the movable element 7 may be disposed at the bottom of the base body 2a, so that the electronic device 1 may be moved by the movable element 7. In one embodiment, when not in use, the movable element 7 may be stored inside the base body 2a, and when in use, the movable element 7 may be exposed outside the base body 2a to allow the base 2 to move, while it is not limited thereto. In one embodiment, the movable element 7 may be pivotally connected to the base body 2a or other parts of the base 2, so that the movable element 7 may rotate relative to the base body 2a, while it is not limited thereto.

In addition, in one embodiment, the electronic device 1 may further include a sensor 8 disposed on the base 2, such as on one side of the base 2, but it is not limited thereto. In one embodiment, the drive element 6 may be electrically connected to the sensor 8 and perform transformation according to the sensing result of the sensor 8. For example, during the transition from the first state to the second state or from the second state to the first state, when the sensor 8 senses an object approaching the electronic device 1, the drive element 6 may control the connection mechanism 5 to stop operating based on the sensing result of the sensor 8, thereby suspending the unfolding or folding of the display device 3. When the sensor 8 does not sense an object approaching the electronic device 1, or when the object originally sensed is moving away from the electronic device 1, the drive element 6 may control the connection mechanism 5 to operate based on the sensing result of the sensor 8, thereby continuing the unfolding or folding of the display device 3, but it is not limited thereto. In some embodiments, the sensor 8 may detect the environment in which the electronic device 1 is located to determine whether there is enough space for the electronic device 1 to be fully unfolded. When the environment space is not enough for the electronic device 1 to be fully unfolded, the unfolding or folding is suspended, or no action is performed. In one embodiment, the type of sensor 8 may include an infrared sensor, a temperature sensor, a millimeter wave sensor, a lidar, a laser sensor, a rangefinder or various other similar sensors, or similar elements, or a combination thereof, while it is not limited thereto.

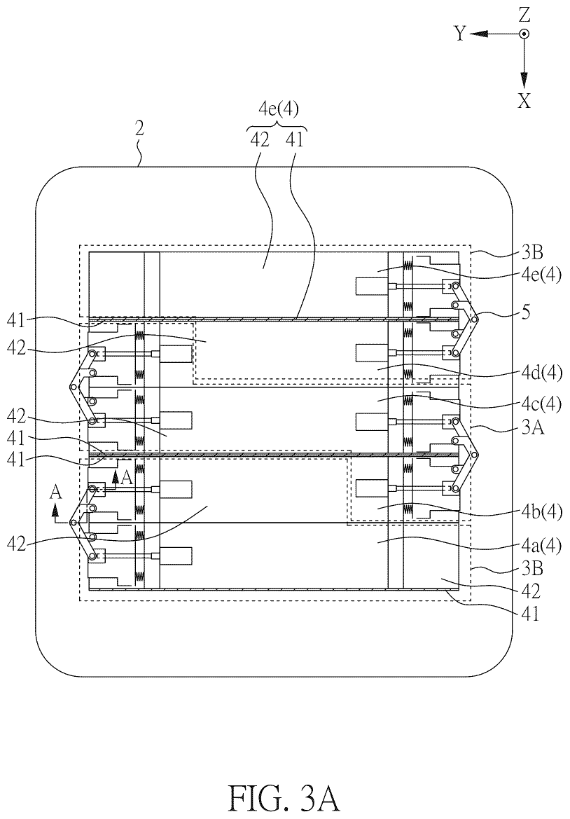

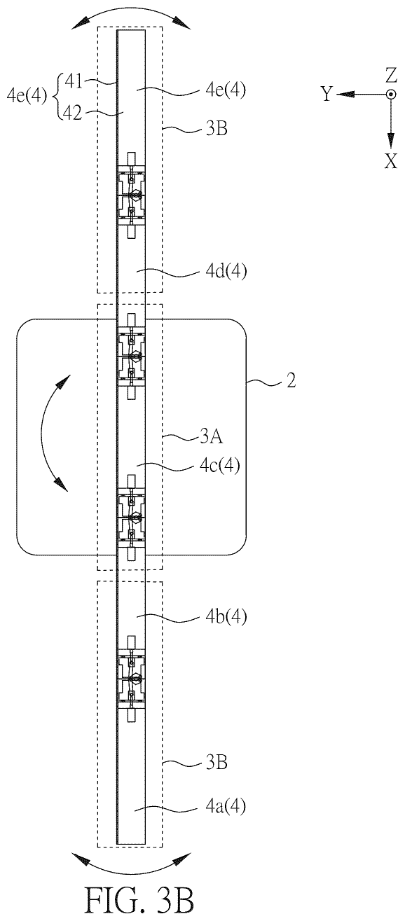

Next, detailed features of the electronic device 1 in the first state and the second state are described in more detail. Please refer to FIG. 3A and FIG. 3B, as well as FIG. 1A to FIG. 2 for assistance. FIG. 3A is a top view of the electronic device 1 in the first state according to an embodiment of the present disclosure, and FIG. 3B is a top view of the electronic device 1 in the second state according to an embodiment of the present disclosure. For example, FIG. 3A and FIG. 3B are presented from a perspective of the negative Z direction.

As shown in FIG. 3A, the display device 3 may include display units 4a~4e, for example. In the top view direction, the display device 3 may include a first portion 3A and a second portion 3B, wherein the first portion 3A may include display unit 4c, a portion of display unit 4b, and a portion of display unit 4d, and the second portion 3B may include display unit 4a, another portion of display unit 4b, another portion of display unit 4d, and display unit 4e. In other words, the first portion 3A corresponds to the center of the display device 3, and the second portion 3B corresponds to the outer portion of the display device 3. It should be noted that the number of display units 4 described above is merely an example, and the coverage of the first portion 3A and the second portion 3B is also an example.

As shown in FIG. 3A, in the top view direction, the first portion 3A and the second portion 3B may overlap with the base 2 in the first state. That is, when the display device 3 is in the folded state, the display units 4a~4e of the display device 3 all overlap with the base 2 in the Z direction, but it is not limited thereto. Furthermore, in one embodiment, in the first state, the back cover 42 of the display unit 4a may be attached to the back cover 42 of the display unit 4b, the display panel 41 of the display unit 4b may be attached to the display panel 41 of the display unit 4c, the back cover 42 of the display unit 4c may be attached to the back cover 42 of the display unit 4d, and the display panel 41 of the display unit 4d may be attached to the display panel 41 of the display unit 4e. Thus, the display device 3 may be in the folded state, but it is not limited thereto. As a result, the size of the display device 3 may be reduced for easier transportation.

As shown in FIG. 3B, in the second state, the first portion 3A overlaps with the base 2 in the Z direction. For example, the display unit 4c, the portion of the display unit 4b, and the portion of the display unit 4d overlap with the base 2 in the Z direction. However, the second portion 3B does not overlap with the base 2 in the second state. For example, the display unit 4a, the other portion of the display unit 4b, the other portion of the display unit 4d, and the display unit 4e do not overlap with the base 2 in the Z direction. In one embodiment, in the second state, all of the display units 4a~4e are arranged consecutively along the X direction, so that the display panels 41 of the display units 4a~4e may be joined. In this way, the display device 3 may be unfolded to form a large-scale display device. It should be noted that the directions shown in FIG. 3A and FIG. 3B are merely schematic for ease of explanation and are not limited thereto in practice. For example, the actual arrangement direction and display direction of the display units 4a~4e in FIG. 3B may differ from the X and Y directions.

Furthermore, in one embodiment, the display device 3 may be connected to the base 2 via at least one display unit 4. For example, in the example of FIG. 3A and FIG. 3B, the display device 3 is connected to the base 2 via the display unit 4c, but it is not limited thereto. In one embodiment, the display unit 4c may be pivotally connected to the base 2, so that the entire display device 3 may still rotate relative to the base 2 after being unfolded, or the display unit 4c may also rotate relative to the base 2 during the unfolding or folding process, but it is not limited thereto.

To enable the electronic device 1 to switch between the first state and the second state, the connection mechanism 5 of the present disclosure is specially designed. The details of the connection mechanism 5 will be further described below. FIG. 4 is a schematic diagram of the connection mechanism 5 according to an embodiment of the present disclosure, which corresponds to the cross-sectional view taken along line A-A′ in FIG. 3A, and please refer to FIG. 1A to FIG, 3B for assistance. FIG. 4 illustrates a single connection mechanism 5, exemplified by the case where the connection mechanism 5 is disposed within the display unit 4 b.

As shown in FIG. 4, a drive element 6 may be disposed in the back cover 42 of the display unit 4b and connected to the screw rod 12. For example, the back cover 42 may accommodate at least a portion of the connection mechanism 5 and the drive element 6. The connection mechanism 5 may include a pivot member 10, a screw rod 12, an inner bracket 14, and a first slider 16.

In one embodiment, the screw rod 12 may be connected (for example, directly or indirectly) to the pivot member 10; for example, one end of the screw rod 12 may be connected to the first slider 16, the first slider 16 may be connected to the pivot member 10, and the other end of the screw rod 12 may be connected to the drive element 6, but it is not limited thereto.

In one embodiment, the inner bracket 14 may be arranged adjacent to the screw rod 12; for example, the screw rod 12 and the first slider 16 may be disposed in the inner bracket 14, the back cover 42 may have a through hole (not shown), and a portion of the pivot member 10 may pass through the through hole and be disposed in the inner bracket 14, while another portion of the pivot member 10 may be exposed outside the back cover 42, but it is not limited thereto.

In one embodiment, the first slider 16 may be disposed between the screw rod 12 and the inner bracket 14. For example, the screw rod 12 and the pivot member 10 are indirectly connected via the first slider 16. The pivot member 10 and the first slider 16 may be pivotally connected, and a portion of the screw rod 12 may extend through the first slider 16. The first slider 16 may include threads corresponding to those of the screw rod 12. Therefore, when the screw rod 12 rotates, the relative position of the first slider 16 and the screw rod 12 in, for example, the Y direction may change, but it is not limited thereto. In one embodiment, the first slider 16 includes a sliding portion 161 and a slider body 162. The sliding portion 161 and the slider body 162 are connected together, for example, fixedly mounted together. In one embodiment, a slide rail 141 may be provided on the inner bracket 14 at a position corresponding to the first slider 16. The sliding portion 161 of the first slider 16 may be disposed on the slide rail 141 of the inner bracket 14 and slide along the slide rail 141, thereby performing, for example, linear motion in the positive and negative Y directions. In one embodiment, when the drive element 6 is operating, the screw rod 12 may rotate. At this moment, the slider body 162 of the first slider 16 moves on the screw rod 12, and at the same time, the sliding portion 161 of the first slider slides along the slide rail 141, so that the first slider 16 moves in the inner bracket 14 so as to perform, for example, linear motion in the positive and negative Y directions, and the movement of the first slider 16 may drive a portion of the pivot member 10 to move in the inner bracket 14, thereby causing the pivot member 10 itself to rotate (the rotation of the pivot member 10 itself will be described in subsequent paragraphs).

In addition, in one embodiment, the connection mechanism 5 may further include an outer bracket 18 and at least one second slider 20. The outer bracket 18 may be disposed adjacent to the inner bracket 14. For example, the outer bracket 18 may be disposed outside the inner bracket 14 and surround at least a portion of the inner bracket 14, but it is not limited thereto. In the Z direction, the second slider 20 may be disposed between the inner bracket 14 and the outer bracket 18. In one embodiment, a position on the outer bracket 18 corresponding to the second slider 20 may include a slide rail 181, and the second slider 20 may be disposed on the slide rail 181, so that the second slider 20 may slide on the slide rail 181. Alternatively, the outer bracket 18 may slide relative to the second slider 20 via the slide rail 181, where the sliding may be linear movement in the positive and negative Y directions. In one embodiment, the second slider 20 may be fixed to the inner bracket 14, so that the outer bracket 18 may slide relative to the inner bracket 14, but it is not limited thereto. In addition, in other embodiments, different from that shown in FIG. 4, the slide rail 181 corresponding to the second slider 20 may be disposed on the inner bracket 14, or another slide rail corresponding to the second slider 20 may be disposed on the inner bracket 14, while it is not limited thereto.

In one embodiment, the connection mechanism 5 further includes at least one stopper 22 and at least one elastic member 24. The stopper 22 may be disposed adjacent to the inner bracket 14, for example, the two may be disposed adjacent to each other in the Y direction, but it is not limited thereto. In one embodiment, the stopper 22 may be fixed to the back cover 42, for example, but it is not limited thereto. The elastic member 24 may be disposed adjacent to the outer bracket 18, for example, the outer bracket 18 may include a pushing portion 182, and the elastic member 24 and the pushing portion 182 may be disposed adjacent to each other in the Y direction. In addition, in the Y direction, the stopper 22 may be disposed between the inner bracket 14 and the elastic member 24, and the elastic member 24 may be disposed between the stopper 22 and the pushing portion 182 of the outer bracket 18. In one embodiment, one end of the elastic member 24 may be connected to the stopper 22, and the other end of the elastic member 24 may be connected to the pushing portion 182 of the outer bracket 18, but it is not limited thereto. In one embodiment, when the pushing portion 182 of the outer bracket 18 pushes the elastic member 24, for example, along the negative Y direction, the elastic member 24 may be compressed, and the outer bracket 18 may move relative to the inner bracket 14 and the stopper 22, for example, along the negative Y direction, but it is not limited thereto. In one embodiment, the elastic member 24 may be, for example, a spring or other similar elastic element, but it is not limited thereto.

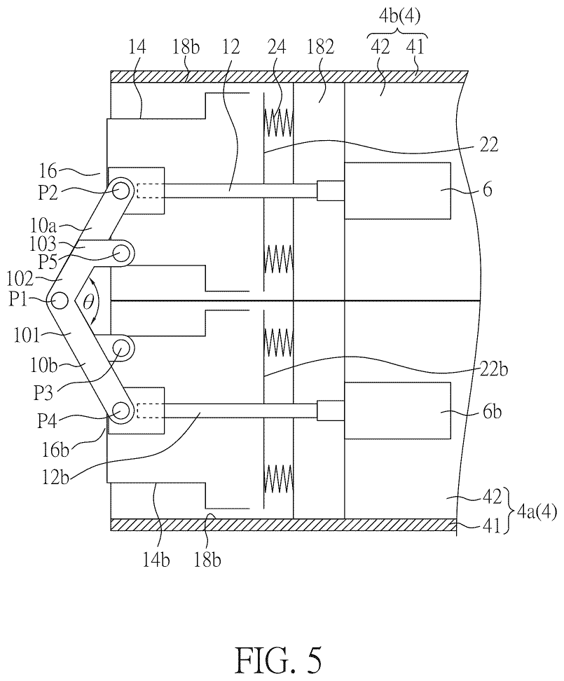

The details of the pivot member 10 will now be described with reference to FIG. 4 and FIG. 5, as well as FIG. 1A to FIG. 3B for assistance. FIG. 5 is a schematic diagram of a connection mechanism 5 according to another embodiment of the present disclosure, which illustrates the details of a single connection mechanism 5 used to connect two adjacent display units (for example, 4a and 4b) in the top view direction (for example, the negative Z direction). It should be noted that, in order to more clearly illustrate important structural details, FIG. 5 is presented in perspective view, and some components in FIG. 4 are omitted, such as the second slider 20, the slide rail 181 of the outer bracket 18, and the slide rail 141 of the inner bracket 14. Furthermore, the proportions of the elements have been scaled to enhance clarity, but it is not limited thereto.

As shown in FIG. 4 and FIG. 5, in one embodiment, the pivot member 10 may include a first pivot member 10a and a second pivot member 10b, wherein the first pivot member 10a and the second pivot member 10b may have mirrored shapes and structures, and the first pivot member 10a and the second pivot member 10b may be pivotally connected together through a first pivot point P1.

As shown in FIG. 5, in one embodiment, the second pivot member 10b may include a first extension arm 101, a second extension arm 102, and a third extension arm 103, with the second extension arm 102 connected between the first extension arm 101 and the third extension arm 103. The first extension arm 101, the second extension arm 102, and the third extension arm 103 may extend in different directions, and the third extension arm 103 may extend in the negative Y direction, for example, but not limited thereto. In one embodiment, there may be an angle θ between the first extension arm 101 and the second extension arm 102, which may be, for example, an obtuse angle, but it is not limited thereto. In one embodiment, there may be another angle between the second extension arm 102 and the third extension arm 103, which may be, for example, an obtuse angle, but it is not limited thereto. Since the first pivot member 10a has a shape and structure that mirrors that of the second pivot member 10b, a detailed description for the first pivot member 10a is deemed unnecessary.

In one embodiment, in the back cover 42 of the display unit 4b, the first pivot member 10a may be indirectly connected to the screw rod 12 via a first slider 16, wherein the first slider 16 and the screw rod 12 may be disposed within the back cover 42 of the display unit 4b. In the display unit 4a adjacent to the display unit 4b, the second pivot member 10b may be connected to another screw rod 12b via another first slider 16b, wherein the other first slider 16b and the other screw rod 12b are disposed within the back cover 42 of the display unit 4a. More specifically, in one embodiment, the first pivot member 10a may further have a second pivot point P2 and a third pivot point P3, wherein the second pivot point P2 may be pivotally connected to the first slider 16 disposed within the display unit 4b, and the third pivot point P3 may be pivotally connected to another inner bracket 14b or another outer bracket 18b disposed within the display unit 4a, or may be pivotally connected to the back cover 42 of the display unit 4a, while it is not limited thereto. In addition, the second pivot member 10b may also have a fourth pivot point P4 and a fifth pivot point P5. The fourth pivot point P4 may be used to pivot with the other first slider 16b disposed in the display unit 4a, and the fifth pivot point P5 may be used to pivot with the inner bracket 14 or the outer bracket 18 disposed in the display unit 4b, or may also be pivoted with the back cover 42 of the display unit 4b, while it is not limited thereto.

Accordingly, the detailed structure of the pivot member 10 can be understood. Next, the operation of a single connection mechanism 5 connected between two adjacent display units (for example, 4a and 4b) when switching between the first state and the second state will be described.

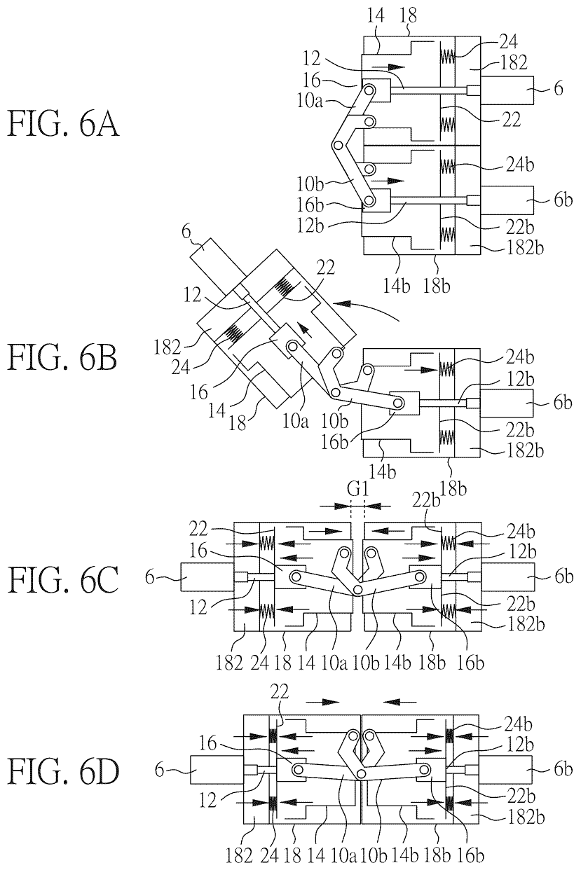

FIG. 6A to FIG. 6D are schematic diagrams illustrating the operation of the connection mechanism 5 during the transition from the first state to the second state according to an embodiment of the present disclosure, and please also refer to FIG. 1A to FIG. 5 for assistance. FIG. 6A illustrates a first stage of the transition of the electronic device 1 from the first state to the second state, FIG. 6B illustrates a second stage of the transition of the electronic device 1 from the first state to the second state, FIG. 6C illustrates a third stage of the transition of the electronic device 1 from the first state to the second state, and FIG. 6D illustrates a fourth stage of the transition of the electronic device 1 from the first state to the second state. It should be noted that, during the transition from the first state to the second state, the display units 4a and 4b may actually rotate relative to the base 2 (for example, as shown in FIG. 3A), and thus FIG. 6A to FIG. 6D do not illustrate the directions in which the components operate in terms of the X, Y, and Z directions.

Initially, the electronic device 1 is in a first state, with adjacent display units 4a and 4b stacked on top of each other. Then, as shown in FIG. 6A, during the first stage of transition from the first state to the second state, the drive element 6 in the display unit 4b may drive the screw rod 12 to rotate, thereby causing the first slider 16 to move linearly within the inner bracket 14, for example, moving the first slider 16 toward the drive element 6. Similarly, in the display unit 4a, the other drive element 6b may drive the other screw rod 12b to rotate, thereby causing the other first slider 16b to move linearly within the other inner bracket 14b, for example, moving the other first slider 16b toward the other drive element 6b.

As shown in FIG. 6B, during the second stage of the transition from the first state to the second state, in the display unit 4b, the drive element 6 continuously drives the screw rod 12 to rotate, causing the first slider 16 to continuously perform linear movement within the inner bracket 14, thereby driving the first pivot member 10a connected thereto to move, for example, toward the drive element 6. Furthermore, in the display unit 4a, the other drive element 6b continuously drives the other screw rod 12 b to rotate, causing the other first slider 16b to continuously perform linear movement within the other inner bracket 14b, thereby driving the second pivot member 10b connected thereto to move, for example, toward the other drive element 6b. Because the first pivot member 10a and the second pivot member 10b move in different directions and away from each other, the pivot member 10 itself rotates about the first pivot point P1, with the first pivot member 10a rotating, for example, counterclockwise, and the second pivot member 10b rotating, for example, clockwise, thereby causing the display units 4a and 4b to begin to move away from each other, while it is not limited thereto.

As shown in FIG. 6C, during the third stage of the transition from the first state to the second state, in the display unit 4b, the drive element 6 continues to rotate the screw rod 12, causing the first slider 16 moving within the inner bracket 14 to move to the stopper 22. The first slider 16 is stopped by the stopper 22, thereby stopping the first pivot member 10a. In the display unit 4a, the other drive element 6b continues to rotate the other screw rod 12b, causing the other first slider 16b moving within the other inner bracket 14b to move to the other stopper 22b. The other stopper 22b stops the first slider 16b, thereby stopping the second pivot member 10b. At this moment, the display units 4a and 4b are fully extended, for example, the display units 4a and 4b are arranged in the same direction (for example, the first direction), and the display panels 41 of the display units 4a and 4b are both facing the same direction (for example, the second direction). In addition, it should be noted that, at this moment, the display units 4a and 4b have a spacing G1 in the arrangement direction (for example, the first direction).

As shown in FIG. 6D, in the fourth stage of the transition from the first state to the second state, in the display unit 4b, the drive element 6 continues to drive the screw rod 12 to rotate, and the first slider 16 continues to be stopped by the stopper 22. At this moment, the pushing portion 182 of the outer bracket 18 may move linearly in the direction toward the display unit 4a and compress the elastic member 24, so that the outer bracket 18 may move toward the display unit 4a and drive the first pivot member 10a to rotate counterclockwise. The rotation amplitude at this stage may be smaller than that in the previous stage, while it is not limited thereto. Furthermore, in display unit 4a, because the other drive element 6 continues to drive the other screw rod 12b to rotate, and the other first slider 16b continues to be stopped by the other stopper 22b, the other pushing portion 182b of the other outer bracket 18b in display unit 4a may now move linearly toward display unit 4b, compressing the other elastic member 24b. Consequently, the other outer bracket 18b in display unit 4a may move toward display unit 4b and drive the second pivot member 10b to rotate clockwise (the rotation amplitude may be, for example, smaller than that in the previous stage). Therefore, in the arrangement direction of display units 4a and 4b (for example, the first direction), the outer bracket 18 of the display unit 4b and the other outer bracket 18b in display unit 4a may engage with each other, reducing or substantially eliminating the gap G1 between display units 4a and 4b to achieve a better display effect. Consequently, display units 4a and 4b are fully unfolded and engaged with each other, and the electronic device 1 has transitioned to the second state. Thus, the process of transition from the first state to the second state can be understood.

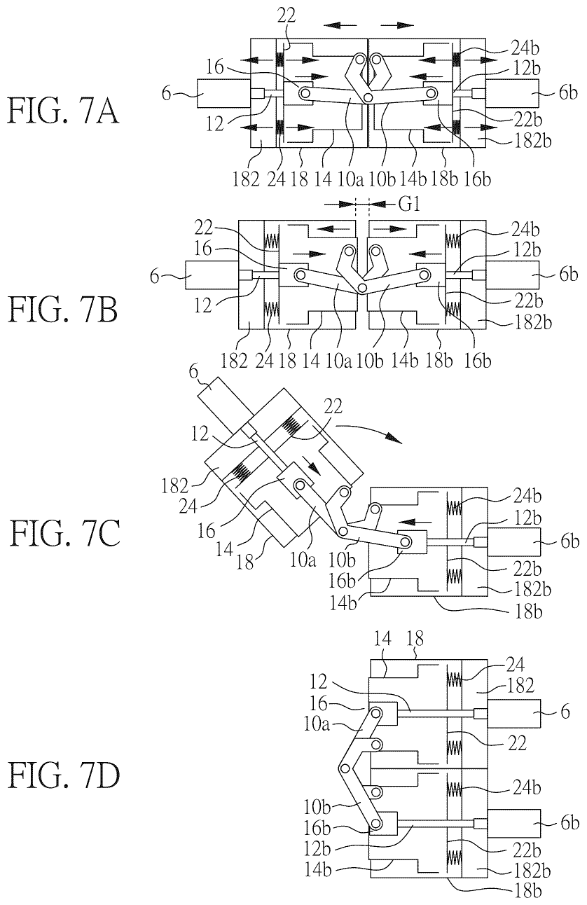

FIG. 7A to FIG. 7D are schematic diagrams illustrating the operation of the connection mechanism 5 during the transition from the second state to the first state according to an embodiment of the present disclosure, and please refer to FIG. 1A to FIG. 6D for assistance. FIG. 7A illustrates a first stage of the transition of the electronic device 1 from the second state to the first state, FIG. 7B illustrates a second stage of the transition of the electronic device 1 from the second state to the first state, FIG. 7C illustrates a third stage of the transition of the electronic device 1 from the second state to the first state, and FIG. 7D illustrates a fourth stage of the transition of the electronic device 1 from the second state to the first state. It should be noted that, during the transition from the second state to the first state, the display units 4a and 4b may actually rotate relative to the base 2 (for example, as shown in FIG. 3A), FIG. 7A to FIG. 7D do not illustrate the directions in which the components operate in terms of the X, Y, and Z directions.

Initially, the electronic device 1 is in the second state, for example, with adjacent display units 4a and 4b in the unfolded state and in contact with each other. Then, as shown in FIG. 7A, during the first stage of the transition from the second state to the first state, the drive element 6 in the display unit 4b drives the screw rod 12 to rotate in another direction (for example, in the opposite direction to that shown in FIG. 6A to FIG. 6D), causing the pushing portion 182 of the outer bracket 18 to move away from the display unit 4a and gradually releasing the elastic member 24. As a result, the outer bracket 18 may move away from the display unit 4a and drive the first pivot member 10a to rotate clockwise. Furthermore, in the display unit 4a, the other drive element 6b may drive the other screw rod 12 to rotate (for example, in the opposite direction to that shown in FIG. 6A to FIG. 6D), causing the other pushing portion 182b of the other outer bracket 18b to move away from the display unit 4b, thereby gradually releasing the other elastic member 24b. As a result, the other outer bracket 18b may move away from the display unit 4b and drive the second pivot member 10b to rotate counterclockwise. As the outer bracket 18 and the other outer bracket 18b move away from each other, a gap may be generated between the display units 4a and 4b, which gradually increases.

As shown in FIG. 7B, when the elastic members 24 and 24b are fully released, that is, when the outer bracket 18 and the other outer bracket 18b have returned to the position shown in FIG. 6C, a gap G1 is generated between the display units 4a and 4b. Next, during the second stage of the transition from the second state to the first state, in the display unit 4b, the drive element 6 continuously drives the screw rod 12 to rotate, causing the first slider 16 to move in the inner bracket 14 away from the drive element 6, and driving the first pivot member 10a connected to the first slider 16 to move in the direction away from the drive element 6. Furthermore, in the display unit 4a, the other drive element 6b continuously drives the other screw rod 12b to rotate, causing the other first slider 16b to move in the other inner bracket 14b away from the other drive element 6b, and driving the second pivot member 10b connected to the other first slider 16b to move in the direction away from the other drive element 6b.

Next, as shown in FIG. 7C, in the third stage of the transition from the second state to the first state, in the display unit 4b, the first slider 16 continues to move in the inner bracket 14 in a direction away from the drive element 6 and continues to drive the first pivot member 10 a to move, causing at least a portion of the first pivot member 10a to gradually separate from the inner bracket 14. Furthermore, in the display unit 4a, the other first slider 16b continues to move in the other inner bracket 14b in a direction away from the other drive element 6b and continues to drive the second pivot member 10b to move, causing at least a portion of the second pivot member 10b to gradually separate from the other inner bracket 14b. Since the first pivot member 10a and the second pivot member 10b move in different directions and approach each other, the pivot member 10 itself rotates around the first pivot point P1, wherein the first pivot member 10a rotates, for example, in a clockwise direction and the second pivot member 10b rotates, for example, in a counterclockwise direction, thereby gradually transitioning the display units 4a and 4b into the retracted state, while it is not limited thereto.

As shown in FIG. 6D, during the fourth stage of the transition from the second state to the first state, the first slider 16 in the display unit 4b has returned to its position as in FIG. 6A, and the other first slider 16b in the display unit 4a has returned to its position as in FIG. 6A. At this moment, the pivot member 10 has returned to its position as in FIG. 6A, and display units 4a and 4b have transitioned to the retracted state. Therefore, the electronic device 1 has fully transitioned from the second state to the first state. Accordingly, the process of transitioning from the second state to the first state can be understood.

Thus, the operation process of the connection mechanism 5 can be understood.

It can be seen that the electronic device 1 of the present disclosure may be converted into the first state or the second state according to the needs of the user, which can solve the disadvantage of large-sized electronic devices in the prior being difficult to carry.

In one embodiment, the present disclosure may determine whether a product in contention falls within the protection scope of the present disclosure at least by the presence or absence of components, component configurations, mechanism observation and/or working methods of the product to determine whether it falls within the protection scope of the present disclosure, while it is not limited thereto. Alternatively, the present disclosure may determine whether a product in contention falls within the protection scope of the present disclosure by the operating modes of the product to determine whether it falls within the protection scope of the present disclosure, while it is not limited thereto.

The features of the various embodiments of the present disclosure may be mixed and matched as desired as long as they do not violate the spirit of the invention or conflict with each other.

The aforementioned specific embodiments should be construed as merely illustrative, and not limiting the rest of the present disclosure in any way.

1. An electronic device having a first state and a second state, comprising:
a base; and
a display device including:
a plurality of display units disposed on the base; and
a plurality of connection mechanisms, wherein one of the plurality of connection mechanisms connects two adjacent display units of the plurality of display units,
wherein the display device includes a first portion and a second portion, the first portion and the second portion overlap with the base in the first state, the first portion overlaps with the base in the second state, and the second portion does not overlap with the base in the second state,
wherein the one of the plurality of connection mechanisms includes:
a pivot member;
a screw rod connected to the pivot member;
an inner bracket disposed adjacent to the screw rod; and
a first slider disposed between the screw rod and the inner bracket,
wherein rotation of the screw rod causes the first slider to move within the inner bracket, and the first slider drives the pivot member to rotate.

2. The electronic device as claimed in claim 1, wherein the one of the plurality of connection mechanisms further includes an outer bracket and at least one second slider, the outer bracket is disposed adjacent to the inner bracket, and the at least one second slider is disposed between the inner bracket and the outer bracket.

3. The electronic device as claimed in claim 2, wherein the one of the plurality of connection mechanisms includes at least one stopper and at least one elastic member, the at least one stopper is disposed adjacent to the inner bracket, the at least one elastic member is disposed adjacent to the outer bracket, and the at least one stopper is disposed between the inner bracket and the at least one elastic member.

4. The electronic device as claimed in claim 1, further comprising a drive element disposed on at least one of the two adjacent display units and connected to the screw rod.

5. The electronic device as claimed in claim 1, wherein the base is provided with a movable element.

6. The electronic device as claimed in claim 4, further comprising a sensor, wherein the drive element performs transformation based on a sensing result of the sensor.

7. The electronic device as claimed in claim 1, wherein the pivot member includes a first pivot member and a second pivot member, the first pivot member is connected to the first slider of the one of the plurality of connection mechanisms, the first slider is disposed in one of the two adjacent display units, the second pivot member is connected to a further first slider of the one of the plurality of connection mechanisms, and the further first slider is disposed in the other of the two adjacent display units.

8. The electronic device as claimed in claim 1, wherein the two adjacent display units each have a display panel and, in the second state, the display panels of the two adjacent display units are joined to each other.

9. The electronic device as claimed in claim 1, wherein, in the first state, the two adjacent display units at least partially overlap in a specific direction.

10. The electronic device as claimed in claim 1, wherein one of the two adjacent display units further comprises a drive element and a back cover, the drive element is connected to the screw rod, and the back cover accommodates the drive element and at least a portion of the connection mechanism.

11. The electronic device as claimed in claim 1, wherein the display device is connected to the base via at least one display unit.

12. The electronic device as claimed in claim 4, wherein one end of the screw rod is connected to the first slider, the first slider is connected to the pivot member, and the other end of the screw rod is connected to the drive element.

13. The electronic device as claimed in claim 1, wherein the pivot member is pivotally connected to the first slider, a portion of the screw rod extends through the first slider, and the first slider has threads corresponding to those of the screw rod.

14. The electronic device as claimed in claim 1, wherein the first slider includes a sliding portion and a slider body, the sliding portion is connected to the slider body, the inner bracket has a slide rail at a position corresponding to the first slider, the sliding portion of the first slider is disposed on the slide rail of the inner bracket.

15. The electronic device as claimed in claim 2, wherein the outer bracket has at least one slide rail at a position corresponding to the at least one second slider, and the at least one second slider is disposed on the at least one slide rail.

16. The electronic device as claimed in claim 3, wherein the outer bracket includes at least one pushing portion, the at least one elastic member is disposed adjacent to the at least one pushing portion, and the at least one elastic member is disposed between the at least one stopper and the at least one pushing portion.

17. The electronic device as claimed in claim 16, wherein one end of the at least one elastic member is connected to the at least one stopper, and the other end of the at least one elastic member is connected to the at least one pushing portion of the outer bracket.

18. The electronic device as claimed in claim 7, wherein the first pivot member and the second pivot member have mirrored shapes and structures, and the first pivot member and the second pivot member are pivotally connected together via a first pivot point.

19. The electronic device as claimed in claim 18, wherein the first pivot member is connected to the screw rod via the first slider, and the second pivot member is connected to a further screw rod via the further first slider.

20. The electronic device as claimed in claim 18, wherein the second pivot member has a first extension arm, a second extension arm and a third extension arm, the second extension arm is connected between the first extension arm and the third extension arm, the first extension arm, the second extension arm and the third extension arm extend in different directions.
